(19) United States
(12) Patent Application Publication
(10) Pub. No.: US 2026/0276910 A1
(43) Pub. Date: Sep. 17, 2026

(54) PHOTONIC CHIP STRUCTURE AND SEMICONDUCTOR PACKAGE COMPRISING THE SAME

(71) Applicant: SAMSUNG ELECTRONICS CO., LTD., Suwon-si (KR)

(72) Inventors: Jing Cheng LIN, Suwon-si (KR); Jung Hua CHANG, Suwon-si (KR)

(73) Assignee: SAMSUNG ELECTRONICS CO., LTD., Suwon-si (KR)

(21) Appl. No.: 19/339,805

(22) Filed: Sep. 25, 2025

(30) Foreign Application Priority Data
Mar. 14, 2025 (KR) 10-2025-0033602

(51) Int. Cl. G02B 6/42

(52) U.S. Cl. CPC G02B 6/4214

(57) ABSTRACT

A photonic chip structure includes a photonic integrated circuit chip, an electronic integrated circuit chip on the photonic integrated circuit chip, an optical block on the photonic integrated circuit chip, the optical block being spaced apart from the electronic integrated circuit chip in a horizontal direction and having a microlens integrally formed with the optical block that provides a path for optical signals to reach the photonic integrated circuit chip, a protective block on the optical block, the protective block extending in a direction perpendicular to an upper surface of the optical block to protect the microlens, and an intermediate layer between the optical block and the protective block.

### CROSS-REFERENCE TO RELATED APPLICATION

This application is based on and claims priority under 35 U.S.C. § 119 to Korean Patent Application No. 10-2025-0033602, filed on Mar. 14, 2025, in the Korean Intellectual Property Office, the disclosure of which being incorporated by reference herein in its entirety.

### BACKGROUND

The present disclosure relates to a photonic chip structure and a semiconductor package including the same, and more particularly, to a semiconductor package including a photonic chip structure including a photonic integrated circuit chip.

With the rapid development of the electronics industry and the demands of users, electronic devices are becoming increasingly smaller and lighter. As electronic devices become smaller and lighter, semiconductor packages used therein are also becoming smaller and lighter, leading to higher integration of semiconductor devices.

Accordingly, semiconductor packages including various integrated circuits, such as memory chips or logic chips mounted on a package substrate to provide multifunctionality, have been developed. In particular, in recent environments where data traffic is increasing in data centers and communication infrastructures, research on semiconductor packages including photonic integrated circuits has been ongoing.

### SUMMARY

It is an aspect to provide a photonic chip structure with high efficiency and a semiconductor package including the same.

Aspects are not limited to the aspects mentioned above, and other aspects may be clearly understood by those skilled in the art from the following description.

According to an aspect of one or more embodiments, there is provided a photonic chip structure comprising a photonic integrated circuit chip; an electronic integrated circuit chip on the photonic integrated circuit chip; an optical block on the photonic integrated circuit chip, the optical block being spaced apart from the electronic integrated circuit chip in a horizontal direction and having a microlens integrally formed with the optical block that provides a path for optical signals to reach the photonic integrated circuit chip; a protective block on the optical block, the protective block extending in a direction perpendicular to an upper surface of the optical block to protect the microlens; and an intermediate layer between the optical block and the protective block.

According to another aspect of one or more embodiments, there is provided a semiconductor package comprising a first package substrate; a second package substrate on the first package substrate; a semiconductor chip structure on the second package substrate; and a photonic chip structure that is spaced apart from the semiconductor chip structure in a horizontal direction on the second package substrate. The photonic chip structure comprises a photonic integrated circuit chip; an electronic integrated circuit chip on the photonic integrated circuit chip; an optical block on the photonic integrated circuit chip, the optical block being spaced apart from the electronic integrated circuit chip in the horizontal direction and having a microlens integrally formed with the optical block that provides a path for optical signals to reach the photonic integrated circuit chip; a protective block on the optical block, the protective block extending in a direction perpendicular to an upper surface of the optical block to protect the microlens; and an intermediate layer between the optical block and the protective block.

According to yet another aspect of one or more embodiments, there is provided a semiconductor package comprising an optical interposer comprising a grating coupler; a semiconductor chip structure on the optical interposer; an electronic integrated circuit chip that is spaced apart from the semiconductor chip structure in a horizontal direction on the optical interposer; an optical block on the optical interposer, the optical block being spaced apart from the electronic integrated circuit chip in the horizontal direction and having a microlens integrally formed with the optical block that provides a path for optical signals to reach the optical interposer; a protective block on the optical block, the protective block and extending in a direction perpendicular to the upper surface of the optical block to protect the microlens; and an intermediate layer between the optical block and the protective block.

### BRIEF DESCRIPTION OF THE DRAWINGS

Various embodiments will be more clearly understood from the following detailed description taken in conjunction with the accompanying drawings, in which:

FIG. 1 is a schematic cross-sectional view of a semiconductor package according to an embodiment;

FIG. 2A is a schematic cross-sectional view of a photonic chip structure according to an embodiment;

FIG. 2B is a schematic cross-sectional view of a photonic chip structure according to an embodiment;

FIG. 2C is a schematic cross-sectional view of a photonic chip structure according to an embodiment;

FIGS. 3A to 3C are schematic perspective views of an optical block according to some embodiments;

FIG. 4 is a schematic cross-sectional view of a photonic chip structure according to an embodiment;

FIG. 5 is a schematic cross-sectional view of a semiconductor package according to an embodiment; and

FIGS. 6A to 6H are schematic cross-sectional views illustrating a method of manufacturing the semiconductor package according to FIG. 1, according to an embodiment.

### DETAILED DESCRIPTION

Various embodiments are described in detail below with reference to the accompanying drawings. The same reference numerals are used for the same components in the drawings, and redundant descriptions thereof are omitted for conciseness. As used in this specification, a phrase using the form “at least one of A, B, or C” includes within its scope “only A”, “only B”, “only C”, “A and B”, “A and C”, “B and C” and “A, B, and C.”

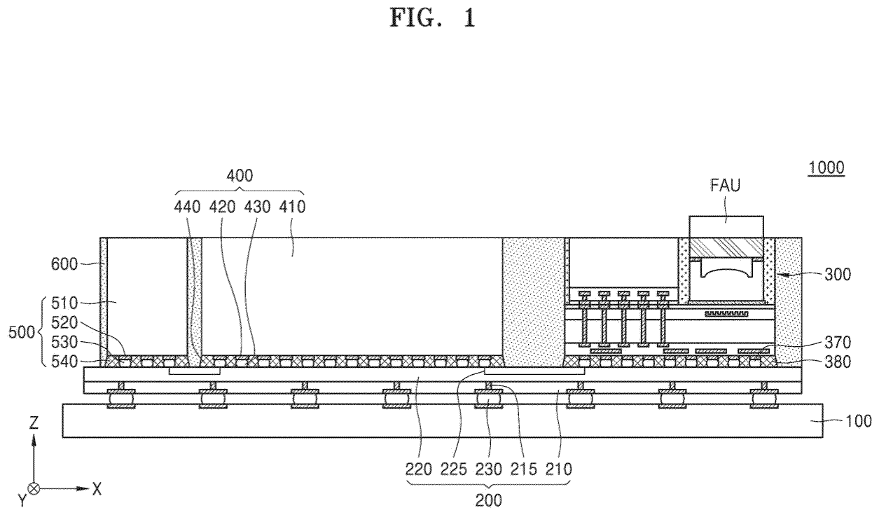

FIG. 1 is a schematic cross-sectional view of a semiconductor package according to an embodiment.

Referring to FIG. 1, a semiconductor package 1000 may include a first package substrate 100, a second package substrate 200, a photonic chip structure 300, a first chip structure 400, a second chip structure 500, and a package molding layer 600. According to some embodiments, the semiconductor package 1000 may include a semiconductor package that communicates with an external device that is external to the semiconductor package 1000 through optical signals. In an embodiment, the semiconductor package 1000 may include an optical engine.

Hereinafter, unless specified otherwise, a direction parallel to an upper surface of the first package substrate 100 is defined as a first horizontal direction (e.g., an X direction), a direction perpendicular to the upper surface of the first package substrate 100 is defined as a vertical direction (e.g., a Z direction), and a direction perpendicular to the first horizontal direction and the vertical direction is defined as a second horizontal direction (e.g., a Y direction).

The first package substrate 100 may include a substrate on which the second package substrate 200 is mounted. In some embodiments, the first package substrate 100 may include a motherboard on which various types of semiconductor chips and packages are mounted. In some embodiments, the first package substrate 100 may include a substrate that receives electrical signals from the second package substrate 200 and transmits the electrical signals to the external device.

According to some embodiments, the first package substrate 100 may include a printed circuit board (PCB) including a wiring pattern and an insulating layer surrounding the wiring pattern therein.

The wiring pattern may include copper (Cu), nickel (Ni), stainless steel, or beryllium copper (BeCu).

The insulating layer may include at least one material selected from among phenol resin, epoxy resin, and polyimide. The insulating layer may include at least one material selected from among, e.g., flame retardant 4 (FR-4), tetrafunctional epoxy, polyphenylene ether, epoxy/polyphenylene oxide, bismaleimide triazine (BT), Thermount, cyanate ester, polyimide, and liquid crystal polymer.

The second package substrate 200 may be mounted on the first package substrate 100. The first chip structure 400, the second chip structure 500, and the photonic chip structure 300 may be mounted on an upper surface of the second package substrate 200.

The second package substrate 200 may electrically connect the first chip structure 400, the second chip structure 500, and the photonic chip structure 300. In an embodiment, the second package substrate 200 may be electrically connected to the first package substrate 100 through connection terminals 230. The second package substrate 200 may electrically connect the first chip structure 400, the second chip structure 500, and the photonic chip structure 300 to the first package substrate 100.

In some embodiments, the second package substrate 200 may include an interposer substrate. In an embodiment, the second package substrate 200 may include a body layer 210 and a wiring layer 220. The wiring layer 220 may be located on an upper surface of the body layer 210. Through electrodes 215 may be formed inside the body layer 210.

The through electrodes 215 may pass through the body layer 210 in the vertical direction. According to some embodiments, the through electrode 215 may include a through silicon via (TSV).

The wiring layer 220 may include a wiring pattern 225. In an embodiment, the wiring pattern 225 may electrically connect the first chip structure 400, the second chip structure 500 and the photonic chip structure 300 to each other. In some embodiments, the wiring pattern 225 may electrically connect the first chip structure 400, the second chip structure 500, and the photonic chip structure 300. In some embodiments, the wiring pattern 225 may electrically connect the first chip structure 400 and the through electrodes 215, the second chip structure 500 and the though electrodes 215, and the photonic chip structure 300 and the through electrodes 215.

The through electrodes 215 may be electrically connected to the first package substrate 100 through pads and bumps formed on a lower surface of the body layer 210.

The second package substrate 200 is described as a silicon interposer including a TSV but embodiments are not limited thereto. For example, in some embodiments, the second package substrate 200 may include a glass interposer including a through glass via (TGV).

In some embodiments, the second package substrate 200 may include a redistribution structure including a redistribution pattern and a redistribution insulating layer surrounding the redistribution pattern.

The redistribution insulating layer may include an insulating material, e.g., a photo-imageable dielectric (PID) resin. In some embodiments, the redistribution insulating layer may further include an inorganic filler. In some embodiments, the redistribution insulating layer may have a multilayer structure in which the redistribution pattern is arranged in each layer.

The redistribution pattern may include a redistribution line pattern extending in at least one of the first horizontal direction or the second horizontal direction, and a redistribution via pattern extending from the redistribution line pattern in the vertical direction.

The redistribution line pattern may be arranged on at least one of an upper surface or a lower surface of the redistribution insulating layer, or may be arranged inside the redistribution insulating layer.

The redistribution via pattern may be connected to a portion of the redistribution line pattern through the redistribution insulating layer. The redistribution pattern may include a conductive material, for example, Cu, aluminum (Al), silver (Ag), tin (Sn), gold (Au), Ni, lead (Pb), titanium (Ti), or an alloy thereof.

The photonic chip structure 300, the first chip structure 400, and the second chip structure 500 may be mounted on the upper surface of the second package substrate 200. According to an embodiment, the photonic chip structure 300 may be located in a peripheral portion of the upper surface of the second package substrate 200.

In some embodiments, the first chip structure 400 may be arranged adjacent to a center portion of the upper surface of the second package substrate 200, and the second chip structure 500 may be spaced apart from the first chip structure 400 in the first horizontal direction. In some embodiments, the second chip structure 500 may be provided in plural and may be disposed on both sides of the first chip structure 400. The photonic chip structure 300 may be spaced apart from the first chip structure 400 in the first horizontal direction. In some embodiments, the photonic chip structure 300 may be spaced apart from the first chip structure 400 in the second horizontal direction.

In FIG. 1, the semiconductor package 1000 is shown to include one first chip structure 400, one second chip structure 500, and one photonic chip structure 300, but embodiments are not limited thereto and the number of first chip structures 400, the number of second chip structures 500, and the number of photonic chip structures 300 included in the semiconductor package 1000 may each be more than one. In some embodiments, for example, the semiconductor package 1000 may include one first chip structure 400, four second chip structures 500, and four photonic chip structures 300.

The first chip structure 400 may include a first chip body 410, first chip pads 420, and first chip bumps 430. Herein, the first chip structure 400 may include a non-memory chip structure including a non-memory device.

In an embodiment, the first chip body 410 may include, for example, silicon. In some embodiments, the first chip body 410 may include a semiconductor element, such as germanium, or a compound semiconductor, such as silicon carbide (SiC), gallium arsenide (GaAs), indium arsenide (InAs), and/or indium phosphide (InP). In some embodiments, the first chip body 410 may have a silicon-on-insulator (SOI) structure. For example, the first chip body 410 may include a buried oxide (BOX) layer. The first chip body 410 may include a conductive region, for example, an impurity-doped well or an impurity-doped structure. In some embodiments, the first chip body 410 may have various device isolation structures, such as a shallow trench isolation (STI) structure.

The first chip structure 400 may include, for example, a system-on-chip, a central processing unit (CPU) chip, a graphics processing unit (GPU) chip, or an application processor (AP) chip. The first chip structure 400 may execute applications supported by the semiconductor package 1000 using a memory device included in the second chip structure 500. For example, the first chip structure 400 may include at least one of a CPU, an AP, a GPU, a neural processing unit (NPU), a tensor processing unit (TPU), a vision processing unit (VPU), an image signal processor (ISP), or a digital signal processor (DSP) to execute specialized operations.

According to an embodiment, the first chip pads 420 on a lower surface of the first chip body 410 may be arranged in at least one of the first horizontal direction or the second horizontal direction. According to an embodiment, upper surfaces of the first chip pads 420 may be coplanar with the lower surface of the first chip body 410, and the first chip pads 420 may be in contact with the first chip bumps 430. The first chip pads 420 may receive electrical signals from the second chip structure 500 or the photonic chip structure 300 through the second package substrate 200, or the first chip pads 420 may transmit electrical signals to the second chip structure 500 or the photonic chip structure 300 through the second package substrate 200.

The first chip pads 420 may include a conductive material that may include, for example, Cu, Au, Ag, Ni, tungsten (W), Al, or a combination thereof. In some embodiments, the first chip pads 420 may further include a barrier material to prevent the conductive material from diffusing out of the first chip pads 420. The barrier material may include, for example, Ti, tantalum (Ta), titanium nitride (TiN), tantalum nitride (TaN), or a combination thereof.

According to an embodiment, the first chip bumps 430 may be attached to the first chip pads 420 of the first chip body 410, respectively. The first chip bumps 430 may include a conductive material including, for example, Sn, Pb, Ag, Cu, or a combination thereof. The first chip bumps 430 may be formed, for example, using solder balls. The first chip bumps 430 may connect the first chip structure 400 to the second package substrate 200.

According to some embodiments, a first underfill material layer 440 may be further disposed on the lower surface of the first chip body 410. The first underfill material layer 440 may surround the first chip bumps 430 between the second package substrate 200 and the first chip structure 400. For example, the first underfill material layer 440 may be formed by any one of a capillary underfill process, a no-flow underfill process, a molded underfill process, and a non-conductive film process. The first underfill material layer 440 may have a tapered shape where a horizontal width of the first underfill material layer 440 decreases in the vertical direction from the second package substrate 200 toward the first chip body 410.

The second chip structure 500 may include a second chip body 510, second chip pads 520, and second chip bumps 530. The second chip structure 500 may include a memory chip structure including a memory device.

The second chip body 510 may include, for example, silicon. In some embodiments, the first chip body 410 may include a semiconductor element, such as germanium, or a compound semiconductor, such as SiC, GaAs, InAs, and InP. In some embodiments, the second chip body 510 may have an SOI structure. For example, the second chip body 510 may include a BOX layer. The second chip body 510 may include a conductive region, for example, an impurity-doped well or an impurity doped structure. In some embodiments, the second chip body 510 may have various device isolation structures, such as an STI structure.

The second chip structure 500 may include, for example, dynamic random-access memory (DRAM), static random-access memory (SRAM), flash memory, electrically erasable and programmable read-only memory (EEPROM), phase-change random-access memory (PRAM), magnetic random-access memory (MRAM), or resistive random-access memory (RRAM). According to an embodiment, the second chip structure 500 may include a memory cell chip having cells of high-bandwidth memory (HBM) DRAM.

According to an embodiment, the second chip pads 520 may be arranged side by side in at least one of the first horizontal direction or the second horizontal direction on a lower surface of the second chip body 510. According to an embodiment, upper surfaces of the second chip pads 520 may be coplanar with the lower surface of the second chip body 510, and the second chip pads 520 may be in contact with the second chip bumps 530. The second chip pads 520 may receive electrical signals from the first chip structure 400 or the photonic chip structure 300 through the second package substrate 200, or the second chip pads 520 may transmit electrical signals to the first chip structure 400 or the photonic chip structure 300 through the second package substrate 200.

The second chip pads 520 may include a conductive material that may include, for example, Cu, Au, Ag, Ni, W, Al, or a combination thereof. In some embodiments, the second chip pads 520 may further include a barrier material to prevent the conductive material from diffusing out of the first chip pads 420. The barrier material may include, for example, Ti, Ta, TiN, TaN, or a combination thereof.

According to an embodiment, the second chip bumps 530 may be attached to the second chip pads 520 of the second chip body 510, respectively. The second chip bumps 530 may include a conductive material including, for example, Sn, Pb, Ag, Cu, or a combination thereof. The second chip bumps 530 may be formed, for example, using solder balls. The second chip bumps 530 may connect the second chip structure 500 to the second package substrate 200.

According to some embodiments, a second underfill material layer 540 may be further disposed on the lower surface of the second chip body 510. The second underfill material layer 540 may surround the second chip bumps 530 between the second package substrate 200 and the second chip structure 500. For example, the second underfill material layer 540 may be formed by any one of a capillary underfill process, a no-flow underfill process, a molded underfill process, and a non-conductive film process. The second underfill material layer 540 may have a tapered shape where a horizontal width of the second underfill material layer 540 decreases in the vertical direction from the second package substrate 200 toward the second chip body 510.

The first chip structure 400 and the second chip structure 500 are described as a non-memory chip structure and a memory chip structure, respectively, but embodiments are not limited thereto. In some embodiments, the first chip structure 400 may include a memory chip structure including a memory chip and the second chip structure 500 may include a non-memory chip structure including a non-memory device.

The photonic chip structure 300 may be mounted on the second package substrate 200 and spaced apart from the first chip structure 400 and the second chip structure 500 in at least one of the first horizontal direction or the second horizontal direction. In some embodiments, the photonic chip structure 300 may be mounted on the second package substrate 200 in a flip chip manner through connection terminals 370, such as micro-bumps. According to some embodiments, an underfill material layer 380 surrounding the connection terminals 370 may be arranged between the photonic chip structure 300 and the second package substrate 200. The underfill material layer 380 may have substantially the same configuration as the first underfill material layer 440 and the second underfill material layer 540, described in the first chip structure 400 and the second chip structure 500, respectively.

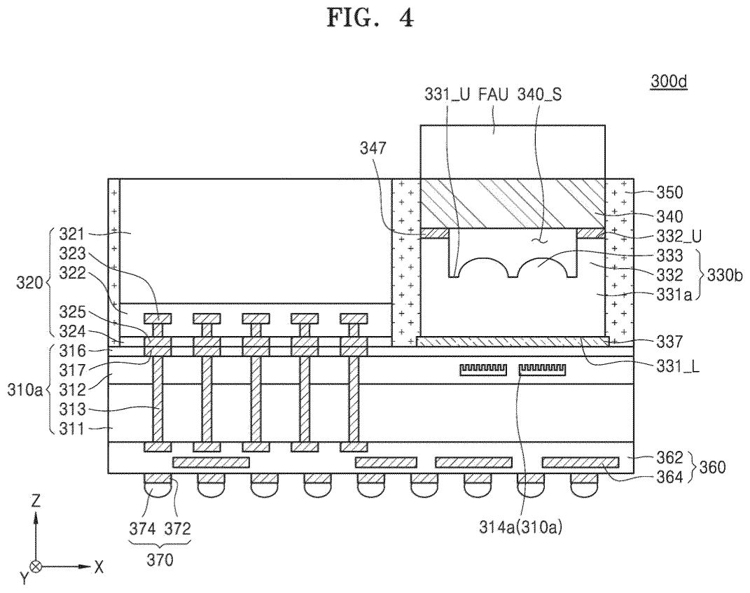

The semiconductor package 1000 may communicate with the external device using optical signals through the photonic chip structure 300. The photonic chip structure 300 may receive optical signals from the external device, convert the received optical signals into electrical signals, and input the converted electrical signals to the first chip structure 400 or the second chip structure 500 through the second package substrate 200. The photonic chip structure 300 may be understood as an optical engine. The photonic chip structure 300 is described in detail below with reference to FIG. 4.

The package molding layer 600 may be formed to surround the first chip structure 400, the second chip structure 500, and the photonic chip structure 300 on the upper surface of the second package substrate 200. In some embodiments, the package molding layer 600 may cover side surfaces of each of the first chip structure 400, the second chip structure 500, and the photonic chip structure 300 and may not cover an upper surface of each of the first chip structure 400, the second chip structure 500, and the photonic chip structure 300. An upper surface of the package molding layer 600 may be coplanar with the upper surface of each of the first chip structure 400, the second chip structure 500, and the photonic chip structure 300. In the same sense, the upper surface of the package molding layer 600 may have the same vertical level as vertical levels of the upper surface of each of the first chip structure 400, the second chip structure 500, and the photonic chip structure 300.

According to some embodiments, the package molding layer 600 may be formed from a thermosetting resin, such as an epoxy resin, a thermoplastic resin such as polyimide, and/or a resin including a reinforcing material, such as an inorganic filler, specifically, Ajinomoto build-up film (ABP), FR-4, BT, or the like, but embodiments are not limited thereto. The package molding layer 600 may be formed from a molding material, such as epoxy molding compound (EMC), or a photosensitive material, such as photo-imageable encapsulant (PIE). In some embodiments, a portion of the package molding layer 600 may include an insulating material, such as a silicon oxide film, a silicon nitride film, or a silicon oxynitride film.

In some embodiments, the package molding layer 600 may fill gaps between the first chip structure 400, the second chip structure 500, the photonic chip structure 300, and the second package substrate 200 through the molded underfill process. In this case, the first underfill material layer 440, the second underfill material layer 540, and the underfill material layer 380 may be omitted.

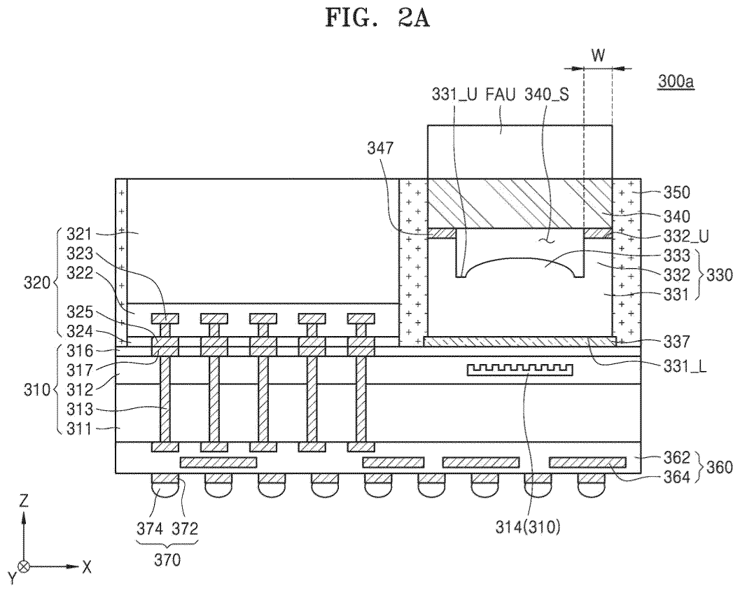

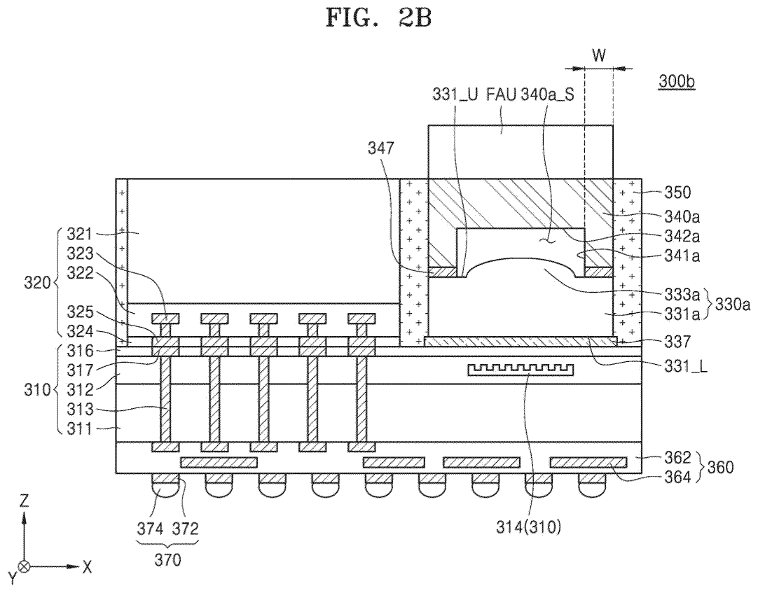

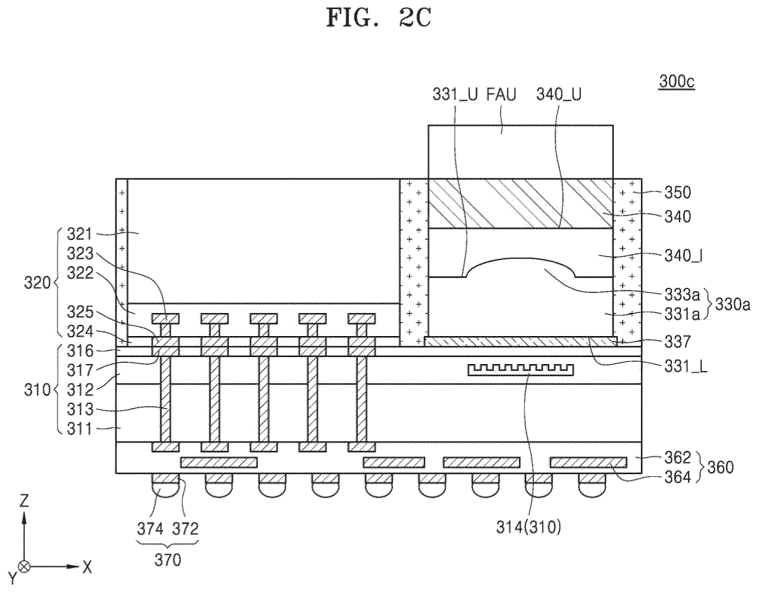

FIG. 2A is a schematic cross-sectional view of a photonic chip structure according to an embodiment.

Referring to FIG. 2A, a photonic chip structure 300a may include a photonic integrated circuit chip 310, an electronic integrated circuit chip 320, an optical block 330, a protective block 340, a molding layer 350, a redistribution structure 360, and connection terminals 370. The photonic chip structure 300a shown in FIG. 2A is an example of the photonic chip structure 300 shown in FIG. 1.

According to an embodiment, the photonic integrated circuit chip 310 may include a first substrate 311, a first interlayer insulating layer 312, through electrodes 313, a grating coupler 314, a first passivation layer 316, and first connection pads 317.

The first substrate 311 may include a semiconductor material, such as silicon or germanium. The first substrate 311 may include an upper surface and an opposite lower surface. The lower surface of the first substrate 311 may include a surface facing the redistribution structure 360. The through electrodes 313 may extend from the upper surface to the lower surface of the first substrate 311 and pass through the first substrate 311. The lower ends of the through electrodes 313 in contact with connection pads may be electrically connected to the redistribution structure 360.

The first interlayer insulating layer 312 may be disposed on the upper surface of the first substrate 311. For example, the first interlayer insulating layer 312 may have a constant thickness and extend along the upper surface of the first substrate 311. According to some embodiments, the first interlayer insulating layer 312 may include an inorganic insulating layer, such as silicon oxide (SiO) or silicon nitride (SiN). In some embodiments, the first interlayer insulating layer 312 may include a polymer material. In some embodiments, the first interlayer insulating layer 312 may include an insulating polymer or a photoimageable dielectric (PID) polymer. For example, the PID polymer may include at least one of a photosensitive polyimide (PSPI), a polybenzoxazole (PBO), a phenol-based polymer, or a benzocyclobutene-based polymer. The first interlayer insulating layer 312 may include two or more insulating materials stacked on top of each other.

The through electrodes 313 may pass through the first substrate 311 and the first interlayer insulating layer 312. In an embodiment, the through electrodes 313 may extend from the lower surface of the first substrate 311 to the first connection pads 317.

The through electrodes 313 may include a conductive material that may include, for example, Cu, Au, Ag, Ni, W, Al, or a combination thereof. In some embodiments, the through electrodes 313 may further include a barrier material to prevent the conductive material from diffusing out of the through electrodes 313. The barrier material may include, for example, Ti, Ta, TiN, TaN, or a combination thereof.

It is shown in FIG. 2A that the through electrodes 313 pass through the first interlayer insulating layer 312 and are connected to the first connection pads 317, but embodiments are not limited thereto. In some embodiments, the through electrodes 313 may pass through only the first substrate 311 to be connected to the first interlayer insulating layer 312. In this case, the first interlayer insulating layer 312 may further include a wiring pattern therein. For example, the wiring pattern may include wiring lines extending in at least one of the first horizontal direction or the second horizontal direction and pattern line vias vertically connecting the wiring lines to electrically connect between the through electrodes 313 and the first connection pads 317.

The grating coupler 314 may be embedded in the first interlayer insulating layer 312. The grating coupler 314 may be configured to couple the optical signals incident to the optical block 330 through a fiber array unit FAU. In an embodiment, the optical signals that reach the grating coupler 314 through the optical block 330 may be coupled to another waveguide. Although not shown, a waveguide and an optical component may be arranged in the first interlayer insulating layer 312, and the grating coupler 314 may be located in one region of the waveguide. The waveguide may extend in the first horizontal direction to a patterned silicon layer. In some embodiments, the waveguide may include a silicon waveguide including silicon, and the first interlayer insulating layer 312 may include a BOX layer. However, embodiments are not limited thereto. In some embodiments, the waveguide may be covered with an oxide layer separated from the first interlayer insulating layer 312. The optical component may be coupled to the waveguide and may convert optical signals into electrical signals or convert electrical signals into optical signals. The optical component may include a photodetector, a photodiode, and/or a modulator.

The grating coupler 314 may be aligned with the optical block 330. For example, the grating coupler 314 may be arranged in the first interlayer insulating layer 312 to vertically overlap the optical block 330. Although one grating coupler 314 is illustrated in FIG. 2A, in some embodiments, a plurality of grating couplers 314 may be provided according to the arrangement of the fiber array unit FAU and microlenses 333 of the optical block 330. The positional relationship between the microlenses 333 and the grating couplers 314 is described below together with the structure of the optical block 330.

The first passivation layer 316 may be disposed on the first interlayer insulating layer 312. The first passivation layer 316 may protect the first interlayer insulating layer 312 and a lower part of the photonic chip structure 300a. The first passivation layer 316 may include an insulating material. In an embodiment, the first passivation layer 316 may include, for example, SiCN.

The first connection pads 317 may be disposed on the first interlayer insulating layer 312. For example, the first connection pads 317 may be embedded in the first passivation layer 316, and side surfaces of the first connection pads 317 may be surrounded by the first passivation layer 316. In some embodiments, upper surfaces of the first connection pads 317 may not be covered by the first passivation layer 316. The upper surfaces of first connection pads 317 may be located on the same vertical level as a vertical level of the upper surface of first passivation layer 316. The first connection pads 317 may be electrically connected to the through electrodes 313 and may be coupled to second connection pads 325 of the electronic integrated circuit chip 320.

According to an embodiment, the electronic integrated circuit chip 320 may be mounted on the photonic integrated circuit chip 310. The electronic integrated circuit chip 320 may be disposed on the photonic integrated circuit chip 310 and may be spaced apart from the optical block 330 in at least one of the first horizontal direction and the second horizontal direction. The electronic integrated circuit chip 320 may be configured to interconnect the photonic integrated circuit chip 310 with the first chip structure 400 and the second chip structure 500. For example, the electronic integrated circuit chip 320 may convert the electrical signals converted by the photonic integrated circuit chip 310 to match the electrical signals used by the first chip structure 400 and the second chip structure 500.

In some embodiments, the horizontal width of the electronic integrated circuit chip 320 may be less than the horizontal width of the photonic integrated circuit chip 310. The footprint of the electronic integrated circuit chip 320 may be less than the footprint of the photonic integrated circuit chip 310.

The electronic integrated circuit chip 320 may include a second substrate 321, a second interlayer insulating layer 322, wiring structures 323, a second passivation layer 324, and second connection pads 325.

The second substrate 321 may include a semiconductor material, such as silicon or germanium. The second substrate 321 may include an active surface and an inactive surface opposite thereto. In some embodiments, the electronic integrated circuit chip 320 may include a plurality of individual devices used to interface with the photonic integrated circuit chip 310. The plurality of individual devices of the electronic integrated circuit chip 320 may be located on the active surface of the second substrate 321. The active surface of the second substrate 321 may include a lower surface of the second substrate 321. For example, the electronic integrated circuit chip 320 may include CMOS drivers, trans-impedance amplifiers, and the like to perform functions, such as controlling high-frequency signaling of the photonic integrated circuit chip 310.

According to an embodiment, the second interlayer insulating layer 322 may be disposed on the upper surface of the second substrate 321. For example, the second interlayer insulating layer 322 may have a constant thickness and may extend along the upper surface of the second substrate 321. According to some embodiments, the second interlayer insulating layer 322 may include an inorganic insulating layer, such as SiO or SiN. In some embodiments, the second interlayer insulating layer 322 may include a polymer material. In some embodiments, the second interlayer insulating layer 322 may include an insulating polymer or a PID polymer. For example, the PID polymer may include at least one of a PSPI, a PBO, a phenol-based polymer, or a benzocyclobutene-based polymer. The second interlayer insulating layer 322 may include two or more insulating materials stacked on top of each other.

The wiring structures 323 may be arranged in the second interlayer insulating layer 322. The wiring structures 323 may be connected to the individual devices located on the active surface of the second substrate 321. The wiring structures 323 may be electrically connected to the second connection pads 325. According to an embodiment, the wiring structures 323 may include wiring lines extending in at least one of the first horizontal direction or the second horizontal direction and wiring line vias vertically connecting the wiring lines to electrically connect the individual devices to the second connection pads 325.

The second passivation layer 324 may be disposed on the second interlayer insulating layer 322. The second passivation layer 324 may protect the second interlayer insulating layer 322 and the wiring structures 323. The second passivation layer 324 may include an insulating material and may include, for example, SiCN.

The second connection pads 325 may be disposed on the second interlayer insulating layer 322. For example, the second connection pads 325 may be embedded in the second passivation layer 324, and side surfaces of the second connection pads 325 may be surrounded by the second passivating layer 324. In some embodiments, lower surfaces of the second connection pads 325 may not be covered by the second passivation layer 324. The lower surfaces of the second connection pads 325 may be located on the same vertical level as the lower surface of the first passivation layer 324. The second connection pads 325 may be electrically connected to the wiring structures 323 and may be coupled to the first connection pads 317 of the photonic integrated circuit chip 310.

In some embodiments, the electronic integrated circuit chip 320 and the photonic integrated circuit chip 310 may be coupled to each other by direct bonding. The direct bonding may include dielectric-to-dielectric bonding, copper-to-copper bonding, and hybrid bonding in which the dielectric-to-dielectric bonding and metal-to-metal bonding are performed together. The first connection pads 317 may be diffusion-bonded to the second connection pads 325 by heat. However, embodiments are not limited thereto. In some embodiments, the electronic direct circuit chip 320 may be electrically connected to the photonic integrated circuit chip 310 by connection terminals, such as solder balls, or an adhesive film, such as an anisotropic film (ACF) or a non-conductive film (NCF).

The optical block 330 may be located on the photonic integrated circuit chip 310. For example, the optical block 330 may be spaced apart from the electronic integrated circuit chip 320 in the first horizontal direction and may be located on the photonic integrated circuit chip 310. The optical block 330 may be located above the grating coupler 314 of the photonic integrated circuit chip 310. The horizontal width of the optical block 330 may be less than the horizontal width of the photonic integrated circuit chip 310.

The optical block 330 may include a body portion 331, a partition portion 332, and microlenses 333.

The optical block 330 may include the body portion 331 having a constant refractive index. For example, the material of the body portion 331 may include silicone, glass, or a polymer. As an example, the optical block 330 may include a material having a light transmittance of more than 85% for light having a wavelength of about 1200 nm to about 1700 nm.

The body portion 331 may form an optical path through which external optical signals are transmitted to the photonic integrated circuit chip 310. Since the body portion 331 of the optical block 330 has a constant refractive index, the light reflection between two materials having different refractive indices may be reduced while the optical signals pass through the body portion 331.

The optical block 330 may include the microlenses 333. In an embodiment, the microlenses 333 may be formed through a nano-imprint process. For example, after preparing a mold in which a microlens pattern is engraved, a polymer or a photosensitive resist may be coated on a surface of a substrate having a material, such as glass. Then, the optical block 330 including the microlenses 333 may be formed by pressing the mold in which a microlens pattern is engraved on the substrate to transfer the microlens shape, and performing a process, such as annealing, washing, and coating. That is, in the optical block 330, the body portion 331 and the microlenses 333 may be integrally formed. In other words, the microlenses 333 may be integrally formed with the formation of the body portion 331 and the optical block 330. In some embodiments, the optical block 330, the body portion 331 and the microlenses 333 may be formed of one block of material. In some embodiments, the microlenses 333 may be formed in the body portion 331 of the optical block 330.

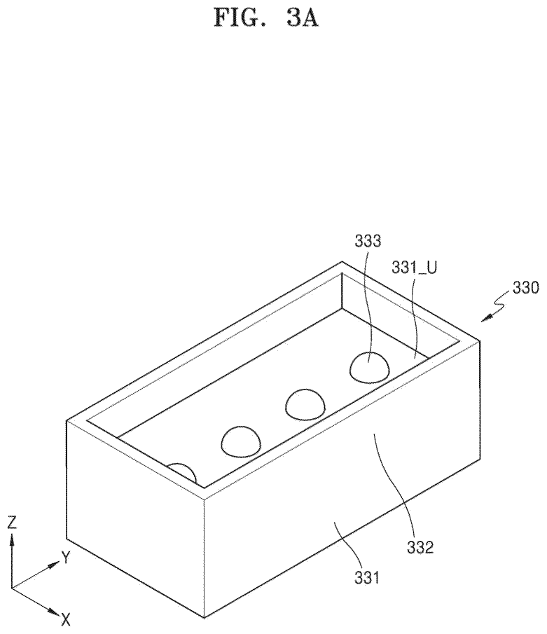

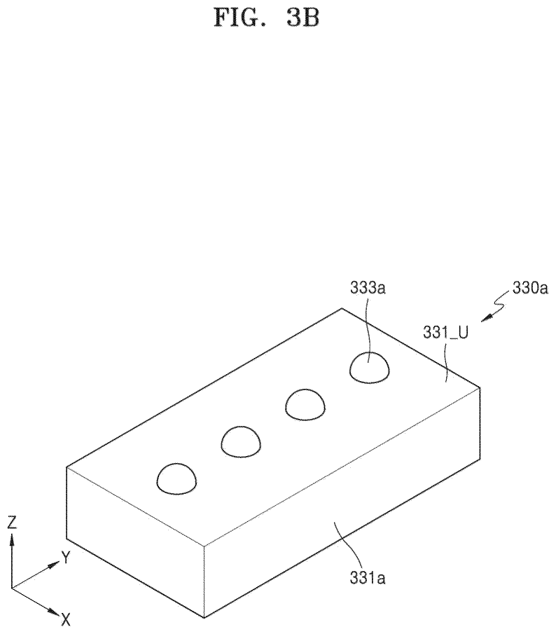

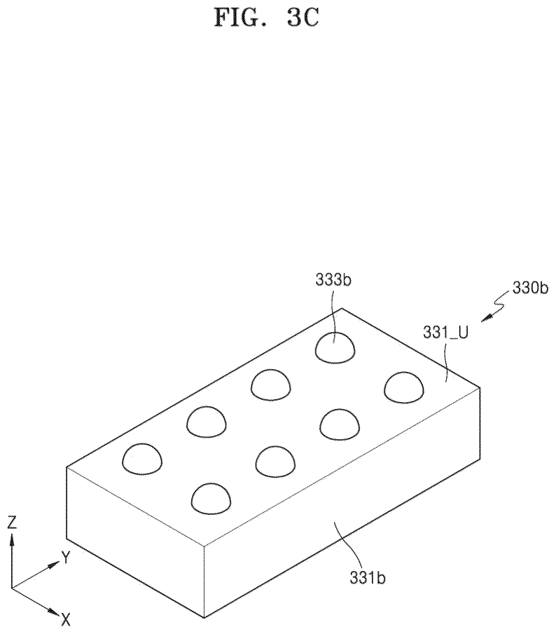

The microlenses 333 may be formed on an upper surface 331_U of the body portion 331. The microlenses 333 may be formed in a row on the upper surface 331_U of the body portion 331. For example, as shown in FIG. 3A, the microlenses 333 may be arranged in a row in the second horizontal direction.

The microlenses 333 may be arranged, corresponding to the grating couplers 314. Referring to FIGS. 2A and 3A, in the photonic chip structure 300 according to various embodiments, the microlenses 333 and the grating couplers 314 may be provided in an array to correspond to each other. The microlenses 333 may correspond to the grating couplers 314, respectively. In an embodiment, the microlenses 333 may overlap the grating couplers 314, respectively, in the vertical direction. For example, when the grating couplers 314 have a 1×20 array on a plane, the microlenses 333 may similarly have a corresponding 1×20 array.

An optical adhesive layer 337 may be provided on a lower surface 331_L of the body portion 331 of the optical block 330. The optical block 330 may be attached to the photonic integrated circuit chip 310 with the optical adhesive layer 337 positioned therebetween. The optical adhesive layer 337 may be aligned with the grating couplers 314 of the photonic integrated circuit chip 310 to attach the optical block 330 onto the photonic integrated circuit chip 310, thereby transmitting the optical signals passing through the optical block 330 to the grating couplers 314.

The partition portion 332 may extend in the vertical direction from upper surface 331_U of the body portion 331 along an edge of the body portion 331. The partition portion 332 may be integrally formed with the body portion 331. For example, in an embodiment, the partition portion 332 may be integrally formed of part of the body portion 331. In an embodiment, the partition portion 332 may be a portion of the body portion 331. In an embodiment, the partition portion 332 may be integrally formed with the body portion 331 from one block of material. In an embodiment, the partition portion 332 may be integrally formed with the body portion 331 from one material. The partition portion 332 may be formed along an edge of the body portion 331 to surround the microlenses 333. For example, the partition portion 332 may be continuously formed along the entire edge of the body portion 331. In this case, the partition portion 332 may have a rectangular frame shape. In some embodiments, the partition portion 332 may be formed discontinuously along an edge of the body portion 331.

The partition portion 332 may have a height that is greater than a height of the microlenses 333. Since the height of the partition portion 332 is greater than the height of the microlenses 333, the microlenses 333 may be protected by the partition portion 333. For example, the microlenses 333 may be prevented from being damaged during a process of combining the optical block 330 with other components.

Since the height of the partition portion 332 is greater than the height of the microlenses 333, the partition portion 332 may prevent the protective block 340 from directly contacting the microlenses 333. That is, the partition portion 332 may form a gap between the microlenses 333 and the protective block 340. In an embodiment, the gap may be filled with an intermediate layer 340_S.

The protective block 340 may be disposed on the optical block 330. For example, the protective block 340 may be disposed on the partition portion 332. The protective block 340 may be configured to protect the optical block 330 during and after the process of processing the photonic chip structure 300. The protective block 340 may be configured to protect the microlenses 333. In some embodiments, the protective block 340 may include a lower surface in contact with the partition portion 332 and an upper surface opposite to the lower surface thereof.

The lower surface of the protective block 340, that is, a surface facing the microlenses 333, may be parallel to the upper surface 331_U of the body portion 331 and may include a smooth surface. In some embodiments, the lower surface of the protective block 340 may have a surface roughness. As an example, the surface roughness of the lower surface of the protective block 340 may be 1 nm or less.

The protective block 340 may be formed of substantially the same material as the optical block 330. For example, the protective block 340 may include silicon, glass, or a polymer. As an example, the protective block 340 may include a material having a light transmittance of more than 85% for light having a wavelength of about 1200 nm to about 1700 nm.

Like the optical block 330, the protective block 340 may form an optical path through which externally incident optical signals pass.

In some embodiments, the protective block 340 may be attached onto the partition portion 332 of the optical block 330 by an adhesive layer 347. That is, the protective block 340 may be attached to the partition portion 332 of the optical block 330 through the adhesive layer 347 located on an upper surface 332_U of the partition portion 332.

The adhesive layer 347 may include an optical adhesive. The optical adhesive denotes a generally tacky material applied to a path through which light passes and has a high light transmittance to minimize the loss of optical signals.

The intermediate layer 340_S may be located inside the partition portion 332 and formed between the microlenses 333 and the protective block 340. The intermediate layer 340_S may be located within the gap formed by the partition portion 332, as described above. The intermediate layer 340_S may include an air gap, an organic material, or an inorganic material.

In an embodiment, the intermediate layer 340_S may be formed as the air gap. In this case, the partition portion 332 may be in contact with the protective block 340, and the space between the microlenses 333 and the protective block 340 may be filled with air. The intermediate layer 340_S formed as the air gap may have a value of about 1.0, which is the refractive index of air.

In some embodiments, the intermediate layer 340_S may be formed as the organic or inorganic material. For example, the intermediate layer 340_S may be formed as a material, such as SiO₂, an optical adhesive, or an optical polymer. In this case, the intermediate layer 340_S may completely fill the space between the microlenses 333 and the protective block 340.

The intermediate layer 340_S may include a material having a light transmittance of more than 85% for light having a wavelength of about 1200 nm to about 1700 nm. The high light transmittance of more than 85% may ensure efficient light transmission in the O-band (1260 nm to 1360 nm) and C-band (1530 nm to 1565 nm) wavelength bands mainly used in chip-to-photonic (CPO) applications.

In some embodiments, the intermediate layer 340_S may include a material satisfying the condition that a ratio of the refractive index n1 of the optical block 330 to a refractive index n2 of the intermediate layer 340_S is 1.2< (n1/n2)<5. The refractive index relationship may be advantageous in allowing the optical signals to be effectively focused when passing through the microlens 333 of the optical block 330. For example, when the refractive index n1 of the optical block 330 is 1.5 and the refractive index n2 of the intermediate layer 340_S is 1.0, the condition is satisfied with n1/n2=1.5.

When n1/n2<1.2, it may be difficult for light to be converted into collimating light. This difficulty is because the difference in refractive index between the optical block 330 and the intermediate layer 340_S is not sufficient. Thus, the microlens 333 may not effectively perform the light focusing or collimating function. Therefore, for efficiently designing the optical path, the refractive index ratio between the optical block 330 and the intermediate layer 340_S should be greater than 1.2.

The presence of the intermediate layer 340_S may control the light reflection that can occur at the interface between the optical block 330 and the protective block 340, thereby improving the transmission efficiency of the optical signals. In particular, the optical signals focused by the microlenses 333 may be efficiently transferred to the protective block 340.

The fiber array unit FAU may be disposed on the protective block 340. In an embodiment, the fiber array unit FAU may be disposed on the protective block 340 in alignment with the microlenses 333. The external optical signals may enter the protective block 340 and the optical block 330 through optical fibers of the fiber array unit FAU. The fiber array unit FAU may include a unit including a plurality of optical fibers. According to an embodiment, the optical fibers may input/output optical signals of different wavelengths. In some embodiments, the optical fibers may input/output optical signals of multiple wavelengths. For example, the optical signals emitted by the optical fibers may have a plurality of peak wavelengths.

The molding layer 350 may seal the electronic integrated circuit chip 320 and the optical block 330 on the photonic integrated circuit chip 310. The molding layer 350 may cover the upper surface of the first passivation layer 316 of the photonic integrated circuit chip 310 and may surround the side surfaces of the electronic integrated circuit chip 320, the side surfaces of the optical block 330, and the outer surface of the protective block 340. According to an embodiment, the upper surface of the molding layer 350 may be located on the same vertical level as vertical levels of the upper surface of the electronic integrated circuit chip 320 and the upper surface of the protective block 340.

The molding layer 350 may include, for example, a thermosetting resin, such as an epoxy resin, a thermoplastic resin, such as polyimide, or a resin including an inorganic filler, specifically ABF, FR-4, BT, a resin, or the like. In some embodiments, a molding material, such as EMC, or a photosensitive material, such as PIE, may be used.

The redistribution structure 360 may be disposed below the photonic integrated circuit chip 310. The redistribution structure 360 may include a structure that electrically connects the photonic integrated circuit chip 310 to the second package substrate 200 (see FIG. 1). The redistribution structure 360 may be provided on the wiring layer 220 of the second package substrate 200.

According to some embodiments, the redistribution structure 360 may include a redistribution insulating layer 362 and redistribution patterns 364. The redistribution insulating layer 362 may be stacked in the vertical direction, and the redistribution patterns 364 may be provided in the redistribution insulating layer 362. The redistribution insulating layer 362 may include a PID or a PSPI, and the redistribution patterns 364 may include, but are not limited to, a metal or an alloy of metals, such as Cu, Al, W, Ti, Ta, indium (In), molybdenum (Mo), manganese (Mn), cobalt (Co), Sn, Ni, magnesium (Mg), rhenium (Re), beryllium (Be), gallium (Ga), ruthenium (Ru), and the like. In some embodiments, the redistribution patterns 364 may be formed by laminating a metal or a metal alloy on a seed layer including Cu, Ti, TiN, or TiW. The photonic integrated circuit chip 310 may transmit and receive electrical signals to and from the second package substrate 200 through the redistribution patterns 364 of the redistribution structure 360.

According to an embodiment, the connection terminals 370 may be disposed on the lower surface of the redistribution structure 360. The connection terminal 370 may include a chip pad 372 disposed on the lower surface of the redistribution structure 360 in at least one of the first horizontal direction or the second horizontal direction and a chip bump 374 disposed on the chip pad 372.

The chip pad 372 may be located on the lower surface of the redistribution structure 360 to provide a terminal on which the chip bump 374 is to be placed. In an embodiment, the material of the chip pad 372 may include Al. However, embodiments are not limited thereto. The material of the chip pad 372 may include a metal, such as Ni, Cu, Au, Ag, W, Ti, Ta, In, Mo, Mn, Co, Sn, Mg, Re, Be, Ga, Ru, or the like, or an alloy thereof.

The chip bump 374 may include a terminal for electrically connecting the photonic chip structure 300 to the second package substrate 200. In an embodiment, the chip bump 374 may include a solder of a metal material including at least one of Sn, Ag, Cu, and Al.

In the photonic chip structure 300 according to various embodiments, since the microlens 333 is integrally formed in the optical block 330 by a nano-imprint process, it is not necessary to provide a new microlens into the chip structure 300. Accordingly, the photonic chip structure 300 with improved coupling efficiency may be provided by preventing misalignment of microlenses.

FIG. 2B is a schematic cross-sectional view of a photonic chip structure according to an embodiment.

Referring to FIG. 2B, a photonic chip structure 300b may include the photonic integrated circuit chip 310, the electronic integrated circuit chip 320, an optical block 330a, a protective block 340a, the molding layer 350, the redistribution structure 360, and the connection terminals 370. The photonic chip structure 300b shown in FIG. 2B is an example of the photonic chip structure 300 shown in FIG. 1.

In the photonic chip structure 300b illustrated in FIG. 2B, the optical block 330a does not include a partition portion. That is, the optical block 330a may include only a body portion 331a and microlenses 333a. In this case, the microlenses 333a may be integrally formed on the upper surface 331_U of the body portion 331a.

The protective block 340a may be disposed on the upper surface 331_U of the body portion 331a. In this case, the protective block 340a may include a lower surface facing the microlenses 333a, and a groove 341a may be formed in the lower surface into the protective block 340a. One groove 341a may be formed to correspond to all the microlenses 333a. That is, one groove 341a may accommodate all the microlenses 333a.

In some embodiments, the protective block 340a may include a plurality of grooves on the lower surface of the protective block 340a facing the microlenses 333a. Each groove may be arranged to correspond to the respective microlens 333a. For example, the grooves formed in the lower surface of the protective block 340a may receive the microlenses 333a.

The inner surface 342a of the groove 341a facing the microlens 333a may be flat. That is, the inner surface 342a of the groove 341a may have a flat surface. In some embodiments, surface roughness may be formed on the inner surface of the groove 341a. The surface roughness may refer to an unevenness formed finely on the inner surface 342a of the groove 341a. The surface roughness may improve the transmittance of the optical signals or improve the adhesion between the protective block 340a and the intermediate layer 340a_S.

The intermediate layer 340a_S may be located between the optical block 330a and the protective block 340a. The intermediate layer 340a_S may fill the space between microlens 333a and groove 341a. The intermediate layer 340a_S may include an air gap, an organic material, or an inorganic material. For example, the intermediate layer 340a_S may be formed of a material, such as SiO₂, an optical adhesive, or an optical polymer.

The intermediate layer 340a_S may include a material satisfying the condition that the ratio of the refractive index n1 of the optical block 330a to the refractive index n2 of the intermediate layer 340a_S is 1.2< (n1/n2)<5. The refractive index relationship may be advantageous in allowing the optical signals to be effectively focused when passing through the microlens 333a of the optical block 330. When (n1/n2)<1.2, it may be difficult for light to be converted into collimating light. This difficulty is because the difference in refractive index between the optical block 330a and the intermediate layer 340a_S is not sufficient. Thus, the microlens 333a may not effectively perform the light focusing or collimating function.

In some embodiments, the protective block 340a may be attached to the upper surface 331_U of the body portion 331a of the optical block 330a through the adhesive layer 347. The adhesive layer 347 may include an optical adhesive. The optical adhesive, which is a generally tacky material applied to the path through which light passes, has high light transmittance to minimize the loss of optical signals.

FIG. 2C is a schematic cross-sectional view of a photonic chip structure according to an embodiment.

Referring to FIG. 2C, a photonic chip structure 300c may include the photonic integrated circuit chip 310, the electronic integrated circuit chip 320, the optical block 330a, the protective block 340, an intermediate layer 340_I, the molding layer 350, the redistribution structure 360, and the connection terminals 370. The photonic chip structure 300c shown in FIG. 2C is an example of the photonic chip structure 300 shown in FIG. 1.

In the photonic chip structure 300c illustrated in FIG. 2C, the optical block 330a does not include a partition portion, like the optical block 330a illustrated in FIG. 2B. That is, the optical block 330a may include only the body portion 331a and the microlenses 333a. In this case, the microlenses 333a are integrally formed on the upper surface 331_U of the body portion 331a.

The intermediate layer 340_I may be arranged between the protective block 340 and the optical block 330a. The intermediate layer 340_I may prevent the optical block 330a and the protective block 340 from being in direct contact with each other. The intermediate layer 340_I may include a glue or SiO2. The glue may include an optical adhesive. In this case, a relationship of 1.2< (n1/n2)<5 may be established between the refractive index n2 of the intermediate layer 340_I and the refractive index n1 of the optical block 330a. The refractive index relationship may be advantageous in allowing the optical signals to be effectively focused when passing through the microlens 333a of the optical block 330a.

According to some embodiments, a sum of the height of the optical block 330a and a height of the protective block 340 may be less than or equal to 780 μm. In some embodiments, the height of the optical block 330a may be greater than 100 μm, and the height of the protective block 340 may be greater than 50 μm. When the height of the optical block 330a is greater than 100 μm, the optical signals are diffused in the fiber array unit FAU, thereby increasing the allowable range for the alignment error. When the height of the protective block 340 is greater than 50 μm, it is possible to sufficiently secure the process window of the grinding process.

The protective block 340 is spaced apart from the microlens 333a. That is, a gap may be present between the microlens 333a and the protective block 340. The gap may be filled by the intermediate layer 340_I. The optical signals transmitted from or received to the photonic integrated circuit chip 310 may pass through the intermediate layer 340_I, the microlens 333a, and the protective block 340 located in the gap.

For example, the optical signals received from the external device may sequentially pass through the protective block 340, the intermediate layer 340_I, the microlens 333a, and the body portion 331a of the optical block 330a to reach the grating coupler 314 of the photonic integrated circuit chip 310. The optical signals reaching the grating coupler 314 may be transmitted through the waveguide and then converted into electrical signals by the optical component. Conversely, the optical signals transmitted from the photonic integrated circuit chip 310 to the external device may be emitted from the grating coupler 314, may sequentially pass through the optical block 330a including the body portion 331a and the microlens 333a, the intermediate layer 340_I, and the protective block 340, and then may be transmitted to the external device.

At least one of the optical block 330a or the protective block 340 may include a material having a light transmittance of more than 85% for light having a wavelength of about 1200 nm to about 1700 nm. The light transmittance may ensure efficient light transmission in the O-band (1260 nm to 1360 nm) and C-band (1530 nm to 1565 nm) wavelength bands mainly used in CPO applications. As a material of the optical block 330a and/or the protective block 340, Si, SiO2, SiCN, SiN, glass, a polymer, or the like may be used.

FIGS. 3A to 3C are schematic perspective views of an optical block, according to various embodiments.

FIG. 3A is a perspective view of the optical block 330 of FIG. 2A. Referring to FIG. 3A, the optical block 330 includes the body portion 331, the partition portion 332, and the microlenses 333. The body portion 331 includes the lower surface 331_L and the upper surface 331_U. The lower surface 331_L of the body portion 331 faces the photonic integrated circuit chip 310, and the upper surface 331_U of the body portion 331 faces the protective block 340.

The partition portion 332 extends in the vertical direction along the edge of the upper surface 331_U of the body portion 331. The partition portion 332 is continuously formed along the entire edge of the body portion 331 to form a rectangular frame shape. The partition portion 332 may be integrally formed with the body portion 331.

The microlenses 333 are formed on the upper surface 331_U of the body portion 331. As shown in FIG. 3A, the microlenses 333 may be arranged in a row in the second horizontal direction. Each of the microlenses 333 may be aligned with the grating coupler 314 of the photonic integrated circuit chip 310 in the vertical direction. The microlenses 333 are arranged inside the partition portion 332 and surrounded by the partition portion 332.

FIG. 3B is a perspective view of the optical block 330a of FIG. 2B. Referring to FIG. 3B, the optical block 330a includes the body portion 331a and the microlenses 333a. Unlike FIG. 3A, the optical block 330a of FIG. 3B does not include a partition portion.

The body portion 331a includes the lower surface 331_L and the upper surface 331_U. The lower surface 331_L of the body portion 331a faces the photonic integrated circuit chip 310, and the upper surface 331_U of the body portion 331a faces the protective block 340a. The microlenses 333a are formed on the upper surface 331_U of the body portion 331a. As shown in FIG. 3B, the microlenses 333a may be arranged in a row in the second horizontal direction as in FIG. 3A.

FIG. 3C is a perspective view of an optical block according to an embodiment. Referring to FIG. 3C, an optical block 330b includes the body portion 331b and microlenses 333b. Similarly to FIG. 3B, the optical block 330b of FIG. 3C does not include a partition portion.

Unlike FIGS. 3A and 3B, the optical block 330b of FIG. 3C may have two rows of microlenses 333b. Specifically, the microlenses 333b may be arranged in a two-dimensional arrangement in the first horizontal direction and the second horizontal direction. The two-dimensional arrangement may place a greater number of microlenses 333b, supporting more optical signal channels. Embodiments are not limited thereto. In some embodiments, three or more rows of microlenses may be formed.

The arrangement pattern of the microlenses 333 may correspond to the arrangement pattern of the grating couplers 314 of the photonic integrated circuit chip 310. As such, externally incident optical signals may be effectively transmitted to the grating couplers 314 of the photonic integrated circuit chip 310.

FIG. 4 is a schematic cross-sectional view of a photonic chip structure according to an embodiment. A photonic chip structure 300d described with reference to FIG. 4 is an example of the photonic chip structure 300 shown in FIG. 1, and most components and materials constituting the components of the photonic chip structure 300d are the same as or similar to those described above with reference to FIG. 2A. Therefore, for convenience of description, differences between the photonic chip structure 300d of FIG. 4 and the photonic chip structure 300a of FIG. 2A are mainly described and repeated description is omitted for conciseness.

Referring to FIG. 4, the photonic chip structure 300d may include a photonic integrated circuit chip 310a, the electronic integrated circuit chip 320, the optical block 330b, the protective block 340, the molding layer 350, the redistribution structure 360, and the connection terminals 370.

The optical block 330b may include a plurality of microlenses 333. The microlenses 333 may be integrally formed with the body portion 331a of the optical block 330b. As described above with reference to FIG. 3C, a plurality of rows of microlenses 333 may be provided. For example, an array of microlenses arranged in a row and spaced apart from each other in the second horizontal direction may be provided in multiple rows in the first horizontal direction.

The photonic integrated circuit chip 310a may include a plurality of grating couplers 314a embedded in the first interlayer insulating layer 312. Each grating coupler 314a may be aligned with the microlens 333 of the optical block 330. In the photonic chip structure 300d of FIG. 4, since the optical block 330b includes two rows of microlenses 333, two rows of grating couplers 314a may be correspondingly arranged in the first interlayer insulating layer 312.

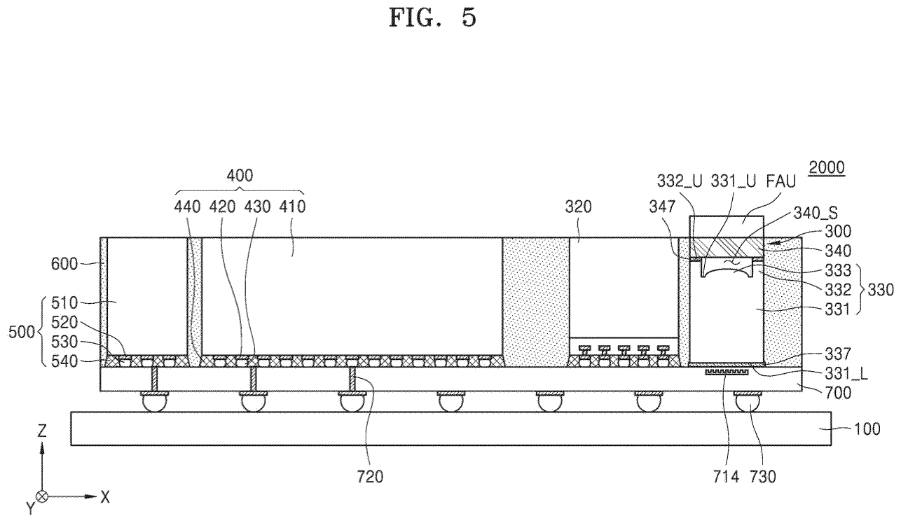

FIG. 5 is a schematic cross-sectional view of a semiconductor package 2000 according to an embodiment. Most components and materials constituting the components of the semiconductor package 2000 described with reference to FIG. 5 are the same as or similar to those described with reference to FIGS. 1 to 4. Therefore, for convenience of description, differences from the semiconductor package 1000 are mainly described and repeated description is omitted for conciseness.

Referring to FIG. 5, the semiconductor package 2000 may include a photonic interposer 700, the photonic chip structure 300, the first chip structure 400, the second chip structure 500, and the package molding layer 600. The semiconductor package 2000 may include a semiconductor package that communicates with the external device through optical signals.

The first chip structure 400, the second chip structure 500, and the photonic chip structure 300 may be mounted on the photonic interposer 700. The first chip structure 400, the second chip structure 500, and the photonic chip structure 300 on the photonic interposer 700 may be spaced apart from each other in at least one of the first horizontal direction and the second horizontal direction. The photonic interposer 700 may electrically connect between the first chip structure 400, the second chip structure 500, and the photonic chip structure 300. In some embodiments, the photonic interposer 700 may receive electrical signals from the first chip structure 400, the second chip structure 500, and the photonic chip structure 300 and transmit the electrical signals to the external device. In some embodiments, through electrodes 720 may be formed inside the photonic interposer 700 to be electrically connected to the first chip structure 400 and the second chip structure 500.

In some embodiments, the photonic interposer 700 may function as the photonic integrated circuit chip 310 of the photonic chip structure 300a described in FIG. 2A. The grating coupler 714 may be embedded in the photonic interposer 700. The grating coupler 714 may be aligned with the optical block 330. For example, the grating coupler 714 may be arranged within the photonic interposer 700 to vertically overlap the optical block 330.

According to an embodiment, the electronic integrated circuit chip 320 may be mounted on the photonic interposer 700. The electronic integrated circuit chip 320 on the photonic interposer 700 may be spaced apart from the optical block 330 in at least one of the first horizontal direction and the second horizontal direction.

The optical block 330 may be located on the photonic interposer 700. For example, the optical block 330 on the photonic interposer 700 may be spaced apart from the electronic integrated circuit chip 320 in the first horizontal direction. The optical block 330 may be located on top of the grating coupler 714 of the photonic interposer 700.

The optical block 330 may include the body portion 331, the partition portion 332, and the microlens 333.

The optical block 330 may include the body portion 331 having a constant refractive index. The body portion 331 may form an optical path through which the external optical signals are transmitted to the photonic interposer 700.

The optical block 330 may include the microlens 333. In an embodiment, the microlens 333 may be formed through a nano-imprint process. That is, in the optical block 330, the body portion 331 and the microlens 333 may be integrally formed. The microlens 333 may be formed on the upper surface 331_U of the body portion 331. The microlens 333 may be formed in a row or in multiple rows on the upper surface 331_U of the body portion 331. The microlens 333 may be arranged corresponding to the grating coupler 714.

The optical adhesive layer 337 may be provided on the lower surface 331_L of the body portion 331 of the optical block 330. The optical block 330 may be attached to the photonic interposer 700 with the optical adhesive layer 337 positioned therebetween. The optical adhesive layer 337 may be aligned with the grating coupler 714 of the photonic interposer 700 to attach the optical block 330 onto the photonic interposer 700, thereby transmitting the optical signals passing through the optical block 330 to the grating coupler 714.

The partition portion 332 may extend in the vertical direction from the upper surface 331_U of the body portion 331 along the edge of the body portion 331. The partition portion 332 may be integrally formed with the body portion 331. The partition portion 332 may be formed along the edge of the body portion 331 to surround the microlens 333. For example, the partition portion 332 may be continuously formed along the entire edge of the body portion 331. In this case, the partition portion 332 may have a rectangular frame shape. In some embodiments, the partition portion 332 may be formed discontinuously along the edge of the body portion 331.

When the height of the partition portion 332 is greater than the height of the microlens 333, the protective block 340 of the partition portion 333 may be prevented from directly contacting the microlens 333. That is, the partition portion 332 may form a gap between the microlens 333 and the protective block 340. This gap may be filled with the intermediate layer 340_S.

The protective block 340 may be disposed on the optical block 330. For example, the protective block 340 may be disposed on the partition portion 332. The protective block 340 may be configured to protect the optical block 330 during and after the process of processing the photonic chip structure 300. The protective block 340 may be configured to protect the microlens 333. In some embodiments, the protective block 340 may include a lower surface in contact with the partition portion 332 and an upper surface opposite to the lower surface thereof.

The package molding layer 600 may be formed to surround the first chip structure 400, the second chip structure 500, and the photonic chip structure 300 on the upper surface of the photonic interposer 700. In some embodiments, the package molding layer 600 may cover side surfaces of each of the first chip structure 400, the second chip structure 500, and the photonic chip structure 300, and may not cover an upper surface of each of the first chip structure 400, the second chip structure 500, and the photonic chip structure 300. In this case, the upper surface of the package molding layer 600 may be coplanar with the upper surface of each of the first chip structure 400, the second chip structure 500, and the photonic chip structure 300. In the same sense, the upper surface of the package molding layer 600 may have the same vertical level as vertical levels of the upper surface of each of the first chip structure 400, the second chip structure 500, and the photonic chip structure 300.

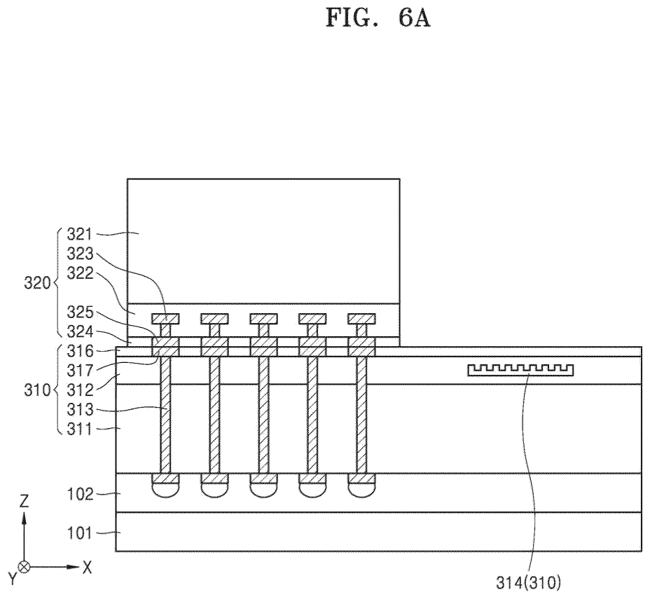

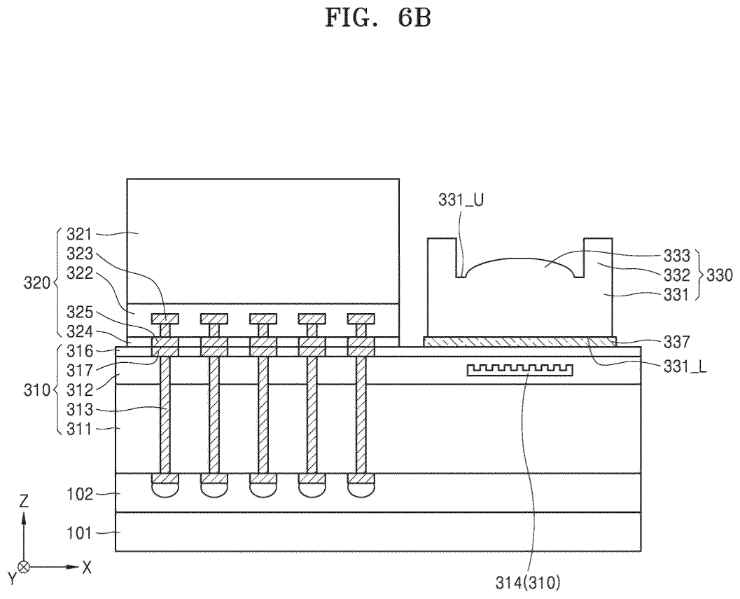

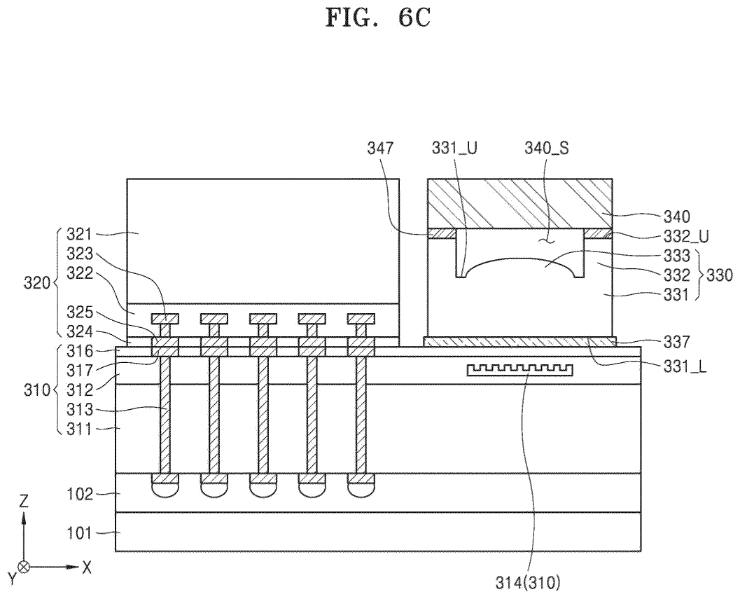

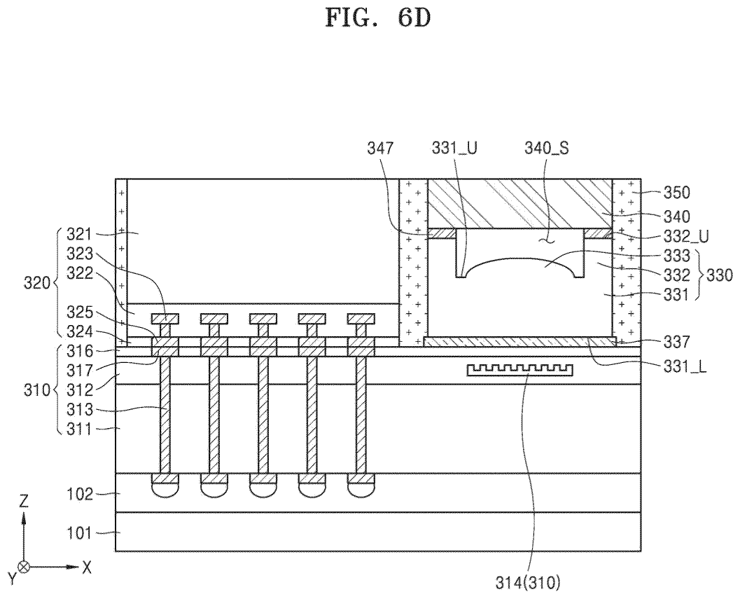

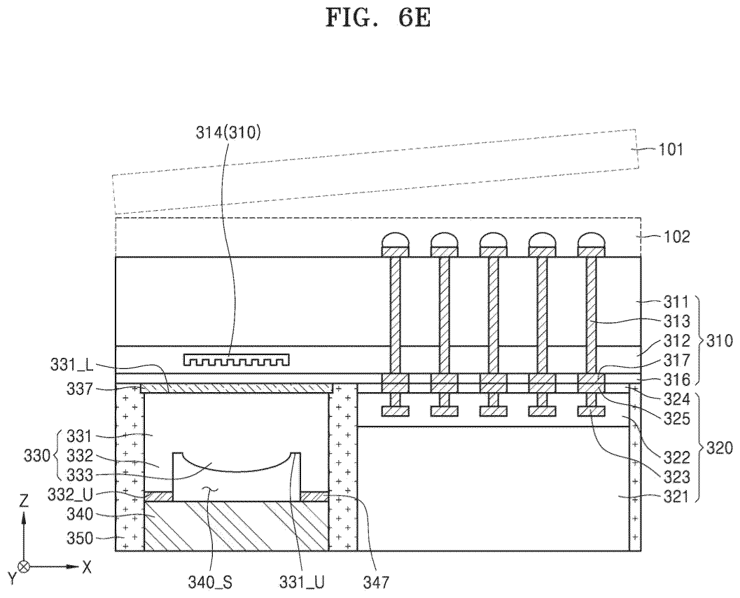

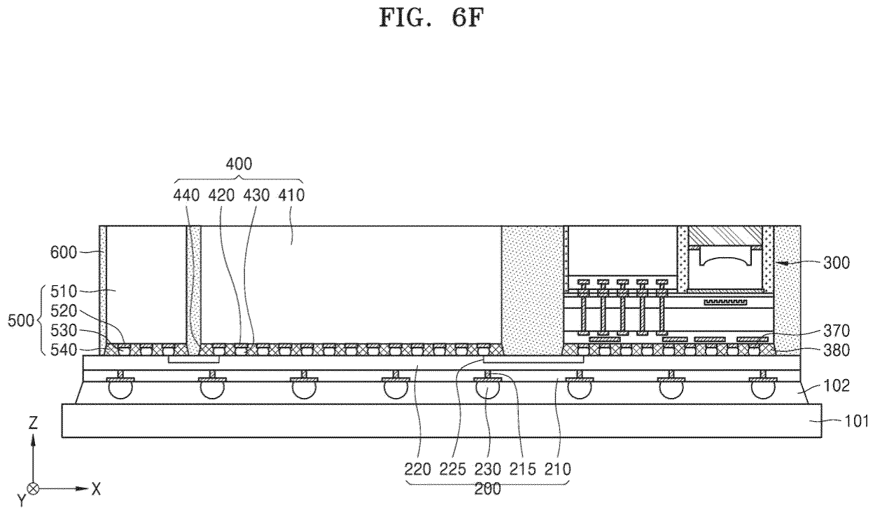

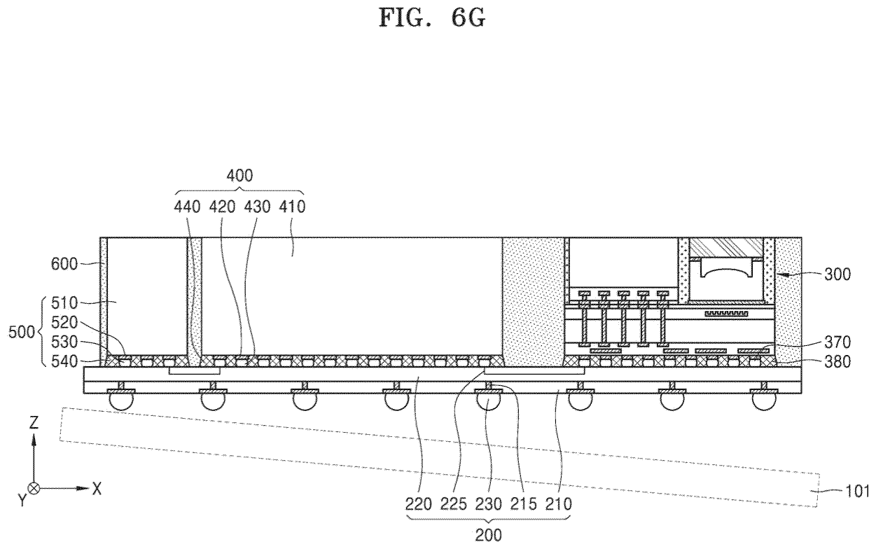

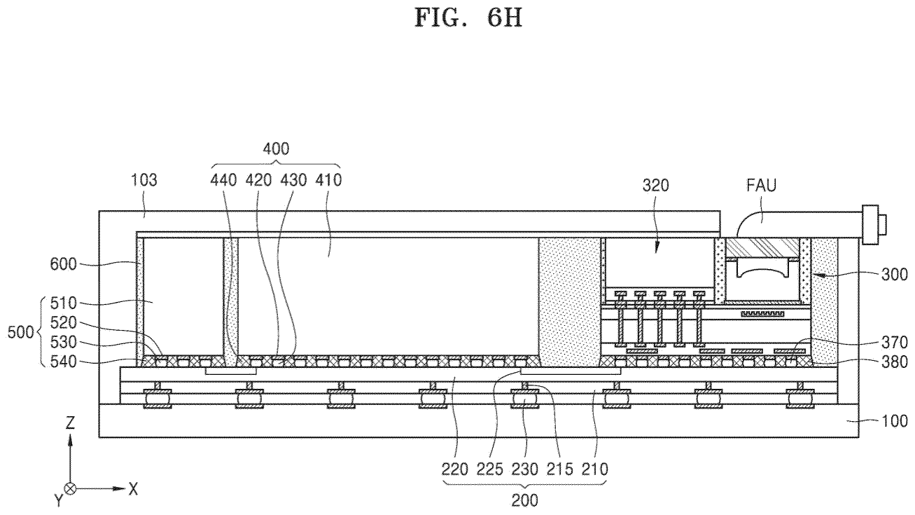

FIGS. 6A to 6H are schematic cross-sectional views of a method of manufacturing the semiconductor package according to FIG. 1.

Referring to FIG. 6A, the photonic integrated circuit chip 310 may be prepared, and the electronic integrated circuit chip 320 may be attached to the photonic integrated circuit chip 310. The electronic integrated circuit chip 320 may be attached to the photonic integrated circuit chip 310 in a face-down manner so that the active surface of the electronic integrated circuit chip 310 and the wiring structures 323 face the photonic integrated circuit chip 310. The electronic integrated circuit chip 320 may be coupled to the photonic integrated circuit chip 310 such that the second connection pads 325 are coupled to the first connection pads 317 of the photonic integrated circuit chip 310.

In some embodiments, the photonic integrated circuit chip 310 and the electronic integrated circuit chip 320 may be coupled by hybrid bonding. The first connection pads 317 may be diffusion bonded to the second connection pads 325 by heat. The diffusion bonding is a method of firmly bonding the two materials by causing atomic diffusion between two metal surfaces. In this process, the interfacial properties between the two bonding surfaces are improved, thereby improving the electrical properties and the mechanical strength.

Referring to FIG. 6B, the optical block 330 is attached to the photonic integrated circuit chip 310. The optical block 330 may include the upwardly convex microlens 333 thereon. The optical block 330 may be arranged such that the microlens 333 is aligned with the grating coupler 314 of the photonic integrated circuit chip 310.

The optical block 330 may be attached to the photonic integrated circuit chip 310 through the optical adhesive layer 337. The optical adhesive layer 337 may be aligned with the grating coupler 314 of the photonic integrated circuit chip 310 to efficiently transmit the optical signals passing through the optical block 330 to the grating coupler 314. The optical adhesive layer 337 may include a material having a light transmittance of 85% or more for light having a wavelength of about 1200 nm to about 1700 nm, thereby ensuring efficient light transmission in the O-band (1260 nm to 1360 nm) and C-band (1530 nm to 1565 nm) wavelength bands.

The microlens 333 may be formed through a nano-imprint process and integrally formed with the optical block 330. The microlens 333 may improve the coupling efficiency of the grating coupler 314. The precise alignment between the microlens 333 and the grating coupler 314 may be achieved through precise positioning of the optical block 330, which is an important factor in maximizing the transmission efficiency of the optical signals.

Referring to FIG. 6C, the protective block 340 is attached to the optical block 330. The protective block 340 may be disposed on the partition portion 332 of the optical block 330. The protective block 340 may protect the microlens 333. The protective block 340 may be attached to the partition portion 332 of the optical block 330 through the adhesive layer 347.

The protective block 340 may include a material having the same or similar refractive index as the refractive index of the material of the optical block 330, so as to minimize light loss that may occur when optical signals are transferred from the optical block 330 to the protective block 340. The placement of the protective block 340 may prevent the microlens 333 from being damaged during the subsequent process.

Referring to FIG. 6D, the molding layer 350 is formed on the photonic integrated circuit chip 310. The molding layer 350 may seal the electronic integrated circuit chip 320 and the optical block 330 on the photonic integrated circuit chip 310. The molding layer 350 may include, for example, a thermosetting resin, such as an epoxy resin, a thermoplastic resin, such as polyimide, or a resin including an inorganic filler, specifically ABF, FR-4, BT, a resin, or the like. In addition, a molding material, such as EMC, or a photosensitive material, such as PIE, may be used.

The molding layer 350 surrounds the side surfaces of the electronic integrated circuit chip 320, the side surfaces of the optical block 330, and the outer surface of the protective block 340, but is not arranged in the inner space of the protective block 340. The mechanical stability of the structure may be improved while ensuring the path through which the optical signals pass. The molding process may be performed using a transfer molding method or a compression molding method.

Referring to FIG. 6E, a carrier substrate 101 is separated from the photonic chip structure 300. A temporary adhesive layer 102 (FIG. 6D) is arranged between the photonic chip structure 300 and the carrier substrate 101. The temporary adhesive layer 102 may be composed of a thermal release adhesive (TRA) or a laser release adhesive (LRA).

In the case of the TRA, the adhesive properties are weakened at a specific temperature (for example, about 180° C. to about 300° C.), making it easy to separate two substrates. In the case of the TRA, when irradiated with a laser of a specific wavelength, the adhesive layer decomposes or its properties may change, making it possible to separate two substrates. The process of separating the carrier substrate 101 should be carefully performed while maintaining the structural integrity of the photonic chip structure 300.

Referring to FIG. 6F, the photonic chip structure 300, the first chip structure 400, and the second chip structure 500 of FIG. 6E may be mounted on the second package substrate 200. Then, the package molding layer 600 is formed on the second package substrate 200. The package molding layer 600 may cover the first chip structure 400, the second chip structure 500, and the photonic chip structure 300.

The first chip structure 400, the second chip structure 500, and the photonic chip structure 300 may be mounted on the second package substrate 200 in a flip chip manner through connection terminals (e.g., the first chip bumps 430, the second chip bumps 530, and/or the connection terminals 370). During flip chip mounting, it is advantageous to make precise alignment between the pads of each structure and the pads of the second package substrate 200, and a metallic bond is formed through a reflow process.

The package molding layer 600 may cover the side surfaces of the first chip structure 400, the second chip structure 500, and the photonic chip structure 300, and may not cover the upper surfaces thereof. In this case, the upper surface of the package molding layer 600 may be coplanar with the upper surface of each of the first chip structure 400, the second chip structure 500, and the photonic chip structure 300. Such a structure may contribute to increasing the heat dissipation efficiency of the semiconductor package 1000.

Referring to FIG. 6G, the carrier substrate 101 is separated from the second package substrate 200. Similar to FIG. 6E, the temporary adhesive layer 102 may be arranged between the second package substrate 200 and the carrier substrate 101. The temporary adhesive layer 102 (FIG. 6E) may temporarily bond the second package substrate 200 to the carrier substrate 101 through a temporary bonding mechanism, such as a TRA or a LRA.

In the separation process, only the carrier substrate 101 may be selectively removed while maintaining the stability of the second package substrate 200 and the structures mounted thereon. This process may be carried out by weakening the adhesive strength of the temporary adhesive layer 102 through heat treatment, laser irradiation, or chemical treatment, and then performing physical separation.

Referring to FIG. 6H, the second package substrate 200 is mounted on the first package substrate 100. The second package substrate 200 may be electrically connected to the first package substrate 100 through the connection terminals 230. Then, the electronic integrated circuit chip 320, the first chip structure 400, and the second chip structure 500 may be encapsulated by a metal shield 103 and the fiber array unit FAU is attached thereto. The metal shield 103 protects the semiconductor package 1000 from electromagnetic interference (EMI). The metal shield 103 may include a metal or a metal alloy, such as Cu, Al, stainless steel, or the like, and may include a material having excellent electromagnetic wave shielding properties.

The fiber array unit FAU is attached to the top of the protective block 340. The fiber array unit FAU may be attached thereto to be exactly aligned with the microlens 333. The fiber array unit FAU may be attached thereto through an active alignment method or a passive alignment method. The active alignment method optimizes the alignment position while measuring the coupling efficiency of the optical signals in real time, while the passive alignment method aligns using structural features or markers.

In the process of attaching the fiber array unit FAU thereto, an ultraviolet (UV) curing adhesive or a thermal curing adhesive may be used to fix the fiber array unit FAU to the protective block 340. The adhesive minimizes the loss of optical signals using a material having a light transmittance of 85% or more for light having a wavelength of from about 1200 nm to about 1700 nm.

The semiconductor package 1000 completed by such a manufacturing method enables high-efficiency optical communication with the external device, and may provide improved coupling efficiency through the optical block 330 where the microlens 333 is integrally formed.

While various embodiments have been particularly shown and described with reference to the drawings, it will be understood that various changes in form and details may be made therein without departing from the spirit and scope of the following claims.

What is claimed is:

1. A photonic chip structure comprising:
a photonic integrated circuit chip;
an electronic integrated circuit chip on the photonic integrated circuit chip;
an optical block on the photonic integrated circuit chip, the optical block being spaced apart from the electronic integrated circuit chip in a horizontal direction and having a microlens integrally formed with the optical block that provides a path for optical signals to reach the photonic integrated circuit chip;
a protective block on the optical block, the protective block extending in a direction perpendicular to an upper surface of the optical block to protect the microlens; and
an intermediate layer between the optical block and the protective block.

2. The photonic chip structure of claim 1, wherein the optical block comprises:
a body portion having a lower surface facing the photonic integrated circuit chip and an upper surface on which the microlens is formed and which faces the protective block; and
a partition portion that extends in a direction perpendicular to the upper surface of the body portion along an edge of the body portion to surround the microlens,
wherein a height of the partition portion is greater than a height of the microlens.

3. The photonic chip structure of claim 2, wherein the protective block is disposed on the partition portion.

4. The photonic chip structure of claim 2, wherein the protective block is attached to an upper surface of the partition portion by an adhesive layer.

5. The photonic chip structure of claim 1, wherein the optical block comprises a body portion having a lower surface facing the photonic integrated circuit chip and an upper surface on which the microlens is formed and which faces the protective block.

6. The photonic chip structure of claim 5, wherein the protective block comprises a groove formed in a direction from a lower surface of the protective block that faces the microlens to an upper surface of the protective block, and
an inner surface of the groove facing the microlens is flat.

7. The photonic chip structure of claim 6, wherein the protective block is attached to the upper surface of the optical block by an adhesive layer.

8. The photonic chip structure of claim 1, wherein the intermediate layer is between the optical block and the protective block, and the optical block is not in direct contact with the protective block.

9. The photonic chip structure of claim 8, wherein:
a sum of a height of the optical block and a height of the protective block is less than or equal to 780 μm,
the height of the optical block is greater than 100 μm, and
the height of the protective block is greater than 50 μm.

10. The photonic chip structure of claim 1, wherein at least one of the optical block or the protective block comprise a material having a light transmittance of more than 85% for light having a wavelength of about 1,200 nm to about 1,700 nm.

11. The photonic chip structure of claim 1, wherein a ratio of a refractive index n1 of the optical block to a refractive index n2 of the intermediate layer is 1.2< (n1/n2)<5.

12. The photonic chip structure of claim 1, wherein the photonic integrated circuit chip comprises:
a first substrate,
a first interlayer insulating layer on the first substrate, and
a through electrode that passes through the first substrate and the first interlayer insulating layer,
wherein the first interlayer insulating layer comprises a grating coupler aligned with the microlens of the optical block.

13. The photonic chip structure of claim 1, wherein the optical block is attached to the photonic integrated circuit chip by an optical adhesive layer.

14. The photonic chip structure of claim 1, wherein a horizontal width of the photonic integrated circuit chip is greater than a horizontal width of the electronic integrated circuit chip.

15. The photonic chip structure of claim 1, further comprising:
a molding layer on the photonic integrated circuit chip, the molding layer surrounding side surfaces of the electronic integrated circuit chip, side surfaces of the optical block, and an outer surface of the protective block,
wherein an upper surface of the molding layer, an upper surface of the electronic integrated circuit chip, and an upper surface of the protective block are on a same vertical level, and the molding layer is not arranged in an inner space of the protective block.

16. A semiconductor package comprising:
a first package substrate;
a second package substrate on the first package substrate;
a semiconductor chip structure on the second package substrate; and
a photonic chip structure that is spaced apart from the semiconductor chip structure in a horizontal direction on the second package substrate,
wherein the photonic chip structure comprises:
a photonic integrated circuit chip;
an electronic integrated circuit chip on the photonic integrated circuit chip;
an optical block on the photonic integrated circuit chip, the optical block being spaced apart from the electronic integrated circuit chip in the horizontal direction and having a microlens integrally formed with the optical block that provides a path for optical signals to reach the photonic integrated circuit chip;
a protective block on the optical block, the protective block extending in a direction perpendicular to an upper surface of the optical block to protect the microlens; and
an intermediate layer between the optical block and the protective block.

17. The semiconductor package of claim 16, wherein the optical block comprises:
a body portion having a lower surface facing the photonic integrated circuit chip and an upper surface on which the microlens is formed and which faces the protective block; and
a partition portion that extends in a direction perpendicular to the upper surface of the body portion along an edge of the body portion to surround the microlens,
wherein a height of the partition portion is greater than a height of the microlens.

18. The semiconductor package of claim 16, wherein the optical block comprises a body portion having a lower surface facing the photonic integrated circuit chip and an upper surface on which the microlens is forms and which faces the protective block.

19. The semiconductor package of claim 16, wherein the intermediate layer is between the optical block and the protective block, and the optical block is not in direct contact with the protective block.

20. A semiconductor package comprising:
an optical interposer comprising a grating coupler;
a semiconductor chip structure on the optical interposer;
an electronic integrated circuit chip that is spaced apart from the semiconductor chip structure in a horizontal direction on the optical interposer;
an optical block on the optical interposer, the optical block being spaced apart from the electronic integrated circuit chip in the horizontal direction and having a microlens integrally formed with the optical block that provides a path for optical signals to reach the optical interposer;
a protective block on the optical block, the protective block and extending in a direction perpendicular to the upper surface of the optical block to protect the microlens; and
an intermediate layer between the optical block and the protective block.
